(19) United States
(12) Patent Application Publication
(10) Pub. No.: US 2026/0205098 A1
(43) Pub. Date: Jul. 16, 2026

(54) Dynamic Thermal Control for a System-on-Chip

(71) Applicant: Google LLC, Mountain View, CA (US)

(72) Inventors: Mohsen Heidarinejad, San Jose, CA (US); Arpit Mittal, San Jose, CA (US)

(73) Assignee: Google LLC, Mountain View, CA (US)

(21) Appl. No.: 19/025,445

(22) Filed: Jan. 16, 2025

(51) Int. Cl. H03K 3/011

(52) U.S. Cl. CPC H03K 3/011

(57) ABSTRACT

Techniques and apparatuses are described for implementing dynamic thermal control for a system-on-chip. In example aspects, a thermal control system of a system-on-chip is a passive system capable of managing heat that is generated by a subsystem of the system-on-chip. The thermal control system dynamically triggers the subsystem to operate at different operation points to address thermal control requirements of the system-on-chip. In more detail, the thermal control system provides flexible and adaptive thermal control policy enforcement by adjusting a temperature threshold and/or feedback signal dynamics (e.g., a feedback time scale). The temperature threshold can be set based on a predicted operation of the subsystem or based on a current operation of the subsystem relative to one or more safety or performance limitations. Through dynamic thermal control, the thermal control system can enforce different throttling limits while the subsystem is operating under different workloads.

### BACKGROUND

An electronic device can be implemented with a system-on-chip (SoC), which can provide many features of the electronic device. An example system-on-chip can include multiple subsystems, such as a central processing unit (CPU), a graphics processing unit (GPU), and/or an image processing unit (IPU). As a user engages with the electronic device, operations of these subsystems can generate heat. Left unchecked, the accumulation of heat within the electronic device can result in a high temperature that can damage the system-on-chip, can damage other components of the electronic device, and/or can reduce a reliability of the electronic device. In some cases, the electronic device can become unsafe for the user to operate.

### SUMMARY

Techniques and apparatuses are described for implementing dynamic thermal control for a system-on-chip. In example aspects, a thermal control system of a system-on-chip is a passive system capable of managing heat that is generated by a subsystem of the system-on-chip. The thermal control system dynamically triggers the subsystem to operate at different operation points to address thermal control requirements of the system-on-chip. In more detail, the thermal control system provides flexible and adaptive thermal control policy enforcement by adjusting a temperature threshold and/or feedback signal dynamics (e.g., a time scale). The temperature threshold can be set based on a predicted operation of the subsystem or based on a current operation of the subsystem relative to one or more safety or performance limitations. Through dynamic thermal control, the thermal control system can enforce appropriate throttling limits while the subsystem operates under different workloads.

Aspects described below include a first method performed by a system-on-chip for implementing dynamic thermal control. The method includes operating, during a first time interval, a subsystem of the system-on-chip at a first operation point. The method also includes determining a second operation point based on a predicted operation of the subsystem. The method additionally includes operating, during a second time interval, the subsystem of the system-on-chip at the second operation point. The method further includes determining a third operation point based on a current operation of the subsystem. The method also includes operating, during a third time interval, the subsystem of the system-on-chip at the third operation point.

Aspects described below include a second method performed by a system-on-chip for implementing dynamic thermal control. The method includes operating, during a first time interval, a subsystem of the system-on-chip at a first operation point. The method also includes determining, during the first time interval, a first temperature threshold based on a predicted operation of the subsystem. The method additionally includes determining, during the first time interval, a second temperature threshold based on a current operation of the subsystem. The method further includes selecting one of the first temperature threshold or the second temperature threshold as a resolved temperature threshold. The method also includes determining a second operation point based on the resolved temperature threshold. The method additionally includes operating, during a second time interval, the subsystem of the system-on-chip at the second operation point.

Aspects described below also include a system-on-chip with at least one subsystem and at least one thermal control system. The system-on-chip is configured to perform, using the at least one subsystem and the at least one thermal control system, any one of the described methods.

Aspects described below also include a system with means for implementing dynamic thermal control for a system-on-chip.

### BRIEF DESCRIPTION OF DRAWINGS

Apparatuses and techniques for implementing dynamic thermal control for a system-on-chip are described with reference to the following drawings. The same numbers are used throughout the drawings to reference like features and components:

FIG. 1 illustrates an example environment in which dynamic thermal control for a system-on-chip can be implemented;

FIG. 2 illustrates an example implementation of a computing device that can implement aspects of dynamic thermal control for a system-on-chip;

FIG. 3 illustrates an example relationship between a subsystem and a thermal control system of a system-on-chip;

FIG. 4 illustrates example operation points of a subsystem;

FIG. 5 illustrates example components of a thermal control system for providing dynamic thermal control for a system-on-chip;

FIG. 6 illustrates an example operation of a thermal control system for implementing dynamic thermal control for a system-on-chip;

FIG. 7 illustrates a first example method for performing dynamic thermal control for a system-on-chip;

FIG. 8 illustrates a second example method for performing dynamic thermal control for a system-on-chip; and

FIG. 9 illustrates an example computing system embodying, or in which techniques may be implemented that enable use of, dynamic thermal control for a system-on-chip.

### DETAILED DESCRIPTION

An electronic device can be implemented with a system-on-chip (SoC), which can provide many features of the electronic device. An example system-on-chip can include multiple subsystems, such as a central processing unit (CPU), a graphics processing unit (GPU), and/or an image processing unit (IPU). As a user engages with the electronic device, operations of these subsystems can generate heat. Left unchecked, the accumulation of heat within the electronic device can result in a high temperature that can damage the system-on-chip, can damage other components of the electronic device, and/or can reduce a reliability of the electronic device. In some cases, the electronic device can become unsafe for the user to operate.

To address this, an electronic device can be implemented with an active cooling system, such as a fan. While operating, the active cooling system can directly reduce an internal temperature of the electronic device by dissipating the accumulated heat within the electronic device and/or transferring the heat to the external environment. To operate, the active cooling system consumes power, which drains power from a power source of the electronic device. Many active cooling systems also have a significant footprint, which requires additional space within the electronic device. As such, an active cooling system may be impractical for some electronic devices, particularly mobile electronic devices, that place a premium on a small form factor and low power consumption.

Instead of using an active cooling system, other electronic devices are implemented with a passive thermal control system that throttles operations of components to manage temperature within the computing device. In contrast to the active cooling system, the passive thermal control system does not consume power during operation and has a smaller footprint. Some passive thermal control systems throttle operations based on a static or fixed thermal control policy. For example, a static thermal control policy can cause the electronic device the throttle operations to keep an internal temperature below a predetermined temperature threshold. Although this may be sufficient for some simple situations or for less-complex electronic devices, a static thermal control policy is unable to account for variations in workload (or usage) of the electronic device. Consequently, the passive thermal control system can cause the electronic device to sacrifice performance in order to ensure the thermal control policy is met, which may result in an unsatisfactory user experience. Considering multiple thermal control policies for different workloads to improve the user experience, however, may not be feasible as it can be challenging to scale and maintain multiple thermal control policies. There is a general need to manage a thermal profile of an electronic device across different workloads while satisfying size constraints and power constraints of the electronic device.

To address this need, techniques are described for implementing dynamic thermal control for a system-on-chip. In example aspects, a system-on-chip includes at least one subsystem and at least one thermal control system. The thermal control system is a passive system capable of managing heat that is generated by the subsystem to protect the subsystem from being damaged due to overheating, to maintain reliability of the system-on-chip, and to avoid creating a potentially unsafe situation for the user to operate a computing device with the system-on-chip. The thermal control system dynamically triggers the subsystem to operate at different operation points to address thermal control requirements of the system-on-chip. In more detail, the thermal control system provides flexible and adaptive thermal control policy enforcement by adjusting a temperature threshold and/or feedback signal dynamics (e.g., a time scale). The temperature threshold can be set based on a predicted operation of the subsystem or based on a current operation of the subsystem relative to one or more safety or performance limitations.

Through dynamic thermal control, the thermal control system can enforce appropriate throttling limits while the subsystem operates under different workloads. In this way, the thermal control system can control an amount of heat that is generated by the subsystem while various applications run and utilize the subsystem on the system-on-chip. In contrast to active cooling systems, the thermal control system can be implemented without significantly impacting a size or power consumption of the electronic device.

### Operating Environment

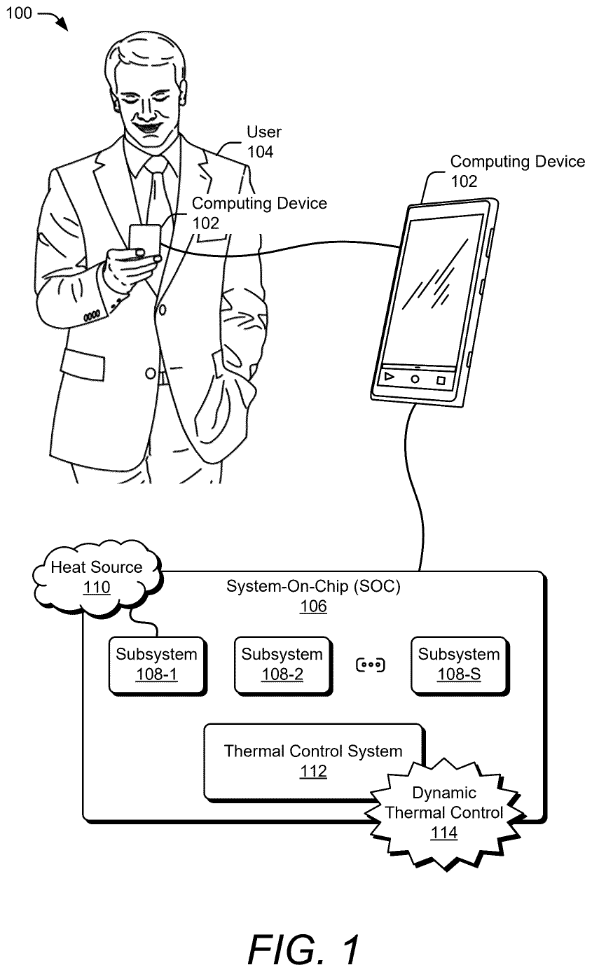

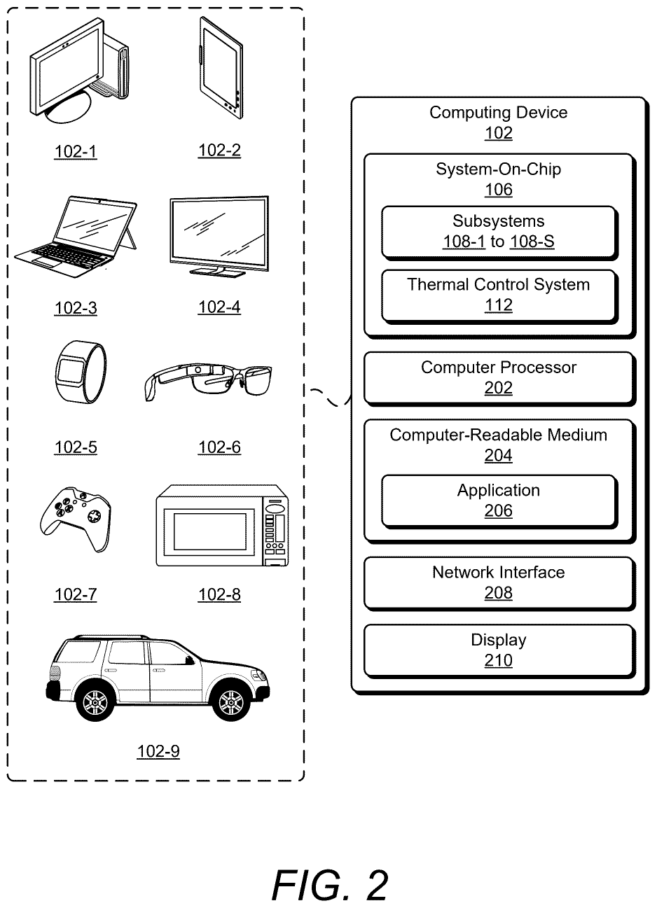

FIG. 1 is an illustration of an example environment 100 in which dynamic thermal control of a system-on-chip can be implemented. In the example environment 100, a computing device 102 provides features and/or services for a user 104. Although depicted as a smartphone, the computing device 102 can include other types of devices, including those described with respect to FIG. 2. The computing device 102 includes at least one system-on-chip (SOC) 106. The system-on-chip 106 can be implemented with electronic circuitry, a microprocessor, memory, input-output (I/O) control logic, communication interfaces, firmware, and/or software useful to provide functionalities of the computing device 102.

The system-on-chip 106 includes multiple subsystems 108-1, 108-2 . . . 108-S, where S represents a positive integer. The subsystems 108 can also be referred to as agents, modules, intellectual-property blocks (IP blocks), or intellectual-property cores. Example subsystems 108 can include a central processing unit (CPU), a graphics processing unit (GPU), an image processing unit (IPU), a modem, a digital signal processor (DSP), a tensor processing unit (TPU), a neural processing unit (NPU), an image processing unit (IPU), a power processing unit (PPU), a display, a speaker, a processor, a memory, a sensor, an analog circuit, a digital circuit, components that handle application-specific processing functions, and so forth.

To facilitate independent operation, the subsystems 108 can have independent clock domains, independent voltage domains, independent power domains, or some combination thereof. Variations in the clock domains, the voltage domains, and the power domains can be based on the different functionalities provided by the subsystems 108 and/or can be based on different implementations of the subsystems 108. The clock domains enable the subsystems 108 to perform operations based on clock signals that are generated by different sources (e.g., generated by different clock generators or different phase-locked loops). The clock signals associated with different clock domains can have similar or different frequencies and/or phases. The different clock domains provide additional flexibility in designing the system-on-chip 106 and positioning the subsystems 108 within the system-on-chip 106. For instance, with the different clock domains, the subsystems 108 can be positioned relatively far apart compared to subsystems 108 that share a same clock domain.

The voltage domains enable the subsystems 108-1 and 108-2 to use different power supply voltages. The power domains enable the subsystems 108 to independently power on or off. With the different clock domains and the different voltage domains, the subsystems 108 can utilize dynamic voltage and frequency scaling (DVFS) to facilitate thermal control of the system-on-chip 106. With the different power domains, the subsystems 108 can also reduce heat generation by powering off when not in use.

One or more of the subsystems 108 represent a heat source 110. While operating, these subsystems 108 generate heat, which can contribute to increasing an internal temperature of the computing device 102. Left unchecked, the accumulation of heat within the computing device 102 can result in a high temperature that can damage the system-on-chip 106, can damage other components of the computing device 102, and/or can reduce a reliability of the computing device 102. In some cases, the high temperature can cause the computing device 102 to become unsafe for the user 104 to operate.

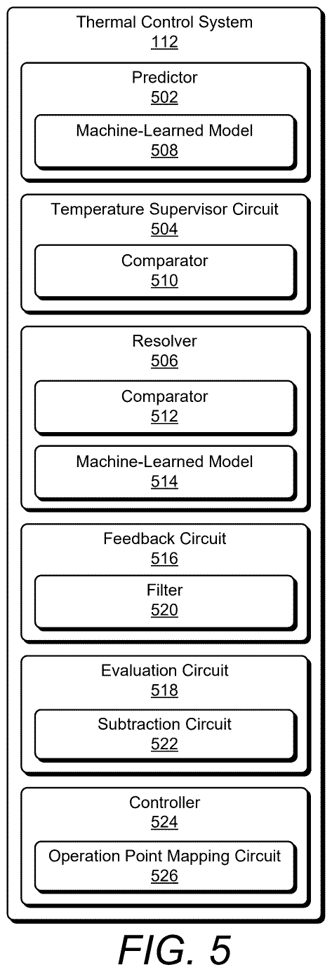

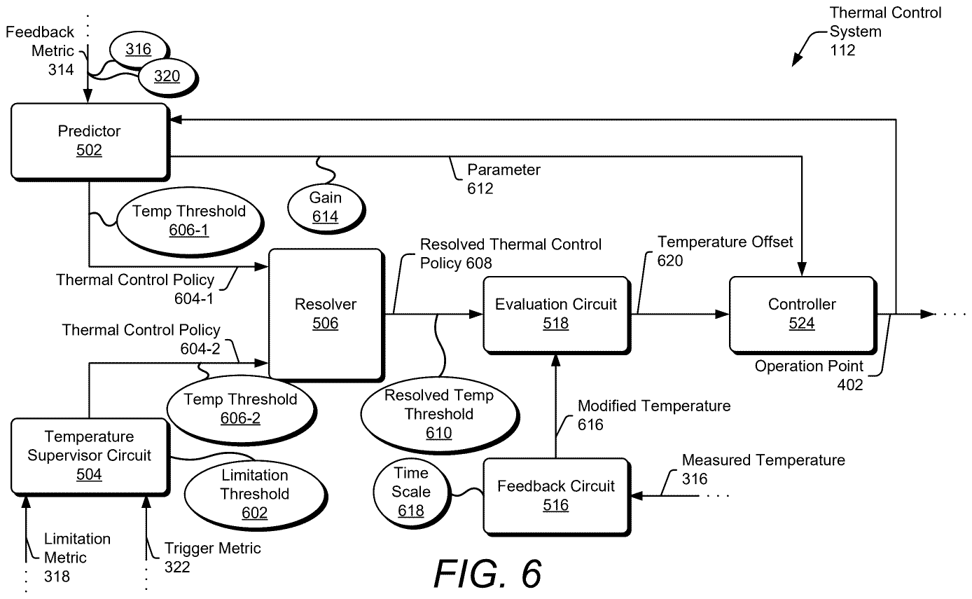

To avoid these situations, the system-on-chip 106 includes at least one thermal control system 112. From a high-level perspective, the thermal control system 112 manages the thermal influence of the system-on-chip 106 to the computing device 102's overall temperature. At a low-level perspective, the thermal control system 112 provides dynamic thermal control 114 by adjusting an operation point of one or more of the subsystems 108 to control an amount of heat that is generated by the system-on-chip 106. An example implementation of the thermal control system 112 is further described with respect to FIGS. 5 and 6.

The thermal control system 112 can be considered another subsystem 108 of the system-on-chip 106. In some implementations, a single thermal control system 112 provides dynamic thermal control 114 for a single subsystem 108. In other implementations, a single thermal control system 112 provides dynamic thermal control 114 for multiple subsystems 108. In still other implementations, multiple thermal control systems 112 provide dynamic thermal control 114 for different sets of subsystems 108 within the system-on-chip 106. The components of the system-on-chip 106 (e.g., the subsystems 108 and the thermal control system 112) can alternatively be implemented within other types of integrated circuits or embedded systems, such as a microchip, an application-specific integrated circuit (ASIC), an application-specific standard product (ASSP), a digital signal processor (DSP), a programmable system-on-chip (PSoC), system-in-package (SiP), controller, and so forth. The computing device 102 is further described with respect to FIG. 2.

FIG. 2 illustrates an example computing device 102. The computing device 102 is illustrated with various non-limiting example devices, including a desktop computer 102-1, a tablet 102-2, a laptop 102-3, a television 102-4, a computing watch 102-5, computing glasses 102-6, a gaming system 102-7, a microwave 102-8, and a vehicle 102-9. Other devices may also be used, including a hearable, a home service device, a smart speaker, a smart thermostat, a baby monitor, a Wi-Fi™ router, a drone, a trackpad, a drawing pad, a netbook, an e-reader, a home automation and control system, a wall display, or another home appliance. Note that the computing device 102 can be wearable, non-wearable but mobile, or relatively immobile (e.g., desktops and appliances). The computing device 102 includes at least one system-on-chip 106. The system-on-chip 106 includes the subsystems 108-1 to 108-S and the thermal control system 112, as described in FIG. 1.

The computing device 102 also includes at least one computer processor 202 and at least one computer-readable medium 204 (e.g., non-transitory computer-readable medium). The computer-readable medium 204 can include memory media and/or non-transitory storage media. An operating system (not shown) embodied as computer-readable instructions on the computer-readable medium 204 can be executed by the computer processor 202.

The computer-readable medium 204 can include one or more applications 206. Execution of the application 206 can involve operating one or more subsystems 108. Example applications 206 can include a messaging application, an application that plays videos, a navigation application, or a gaming application. Different applications 206 can have different performance requirements and cause the subsystems 108 to operate with different workloads. For example, some applications 206 can utilize the first subsystem 108-1, other applications 206 can utilize the second subsystem 108-2, and still other applications 206 can utilize multiple subsystems 108 (e.g., the subsystems 108-1 and 108-2). In general, each application 206 can be associated with a particular thermal usage characteristic, which represents an amount of heat generated by the system-on-chip 106. This heat generation impacts an overall temperature of the computing device 102.

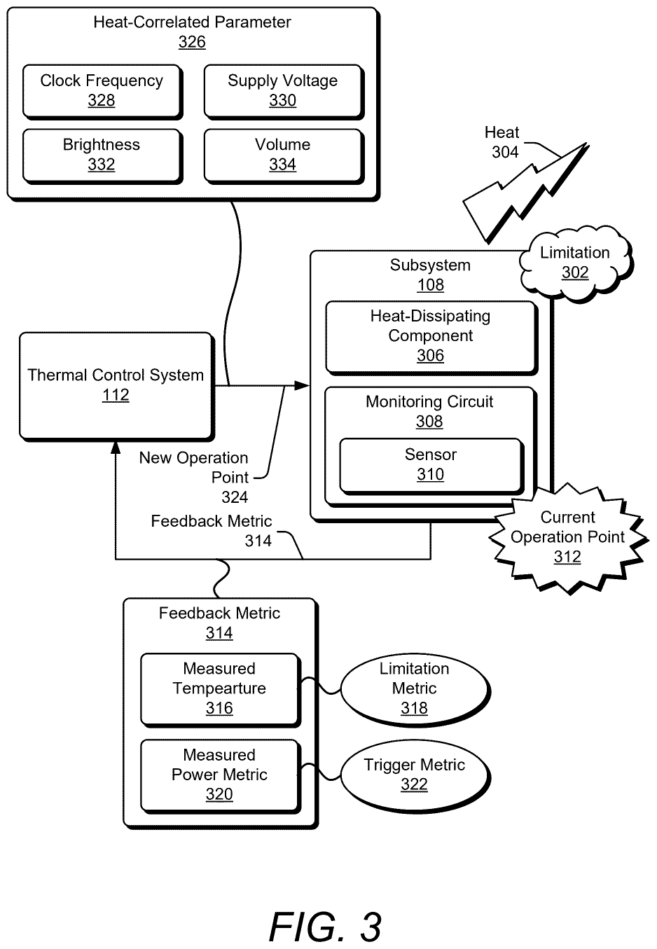

The computing device 102 can additionally include a network interface 208 for communicating data over wired, wireless, or optical networks. For example, the network interface 208 may communicate data over a local-area-network (LAN), a wireless local-area-network (WLAN), a personal-area-network (PAN), a wide-area-network (WAN), an intranet, the Internet, a peer-to-peer network, point-to-point network, a mesh network, Bluetooth™, and the like. The computing device 102 may also include a display 210. An example relationship between the thermal control system 112 and one of the subsystems 108 is further described with respect to FIG. 3.

### Dynamic Thermal Control for a System-on-Chip

FIG. 3. illustrates an example relationship between the subsystem 108 and the thermal control system 112, which are communicatively coupled together. Although a single subsystem 108 is depicted in FIG. 3, it is to be understood that the thermal control system 112 can be coupled to more than one subsystem 108. Some subsystems 108 can have an operation limitation 302. The limitation 302 can represent an operating parameter that is not to be exceeded to avoid compromising an operation of the subsystem 108, a reliability of the subsystem 108, and/or user safety. In many cases, meeting or surpassing the limitation 302 can damage the subsystem 108 and/or decrease a reliability of the subsystem 108. Some limitations 302, such as a safety-based limitation, can represent a maximum instantaneous temperature limit. Keeping an instantaneous temperature measurement of the subsystem 108 below the maximum instantaneous temperature limit can protect the subsystem 108 from damage caused by operating at a high temperature. Other limitations 302, such as a reliability-based limitation, can represent a maximum average temperature limit. Keeping an average temperature measurement of the subsystem 108 below the maximum average temperature limit can preserve a reliability of the subsystem 108 (e.g., can avoid degrading or compromising the reliability of the subsystem 108).

The subsystem 108 is an active component and a heat source 110, which means that the subsystem 108 consumes power and generates heat 304 during operation. The subsystem 108 includes at least one heat-dissipating component 306 and at least one monitoring circuit 308. While active (e.g., while consuming power), the heat-dissipating component 306 generates heat 304, which can contribute to the computing device 102's overall internal temperature. Example heat-dissipating components 306 can include an integrated circuit, a transistor, a resistor, a processor, and so forth.

The monitoring circuit 308 provides information regarding an operation of the subsystem 108 (e.g., an operation of the heat-dissipating component 306) to the thermal control system 112. In some implementations, the monitoring circuit 308 includes at least one sensor 310, which measures a temperature associated with the subsystem 108. The sensor 310 can be positioned on or proximate to the heat-dissipating component 306. In some cases, the monitoring circuit 308 includes multiple temperature sensors 310 to measure the temperature associated with the heat-dissipating component 306. The monitoring circuit 308 can measure or determine other operating parameters of the heat-dissipating component 306 (or more generally of the subsystem 108). For example, in some implementations, the monitoring circuit 308 can measure an amount of power that is consumed by the heat-dissipating component 306.

During operation, the subsystem 108 operates at a current operation point 312. The current operation point 312 represents a current configuration of the subsystem 108. In example implementations, the current operation point 312 can specify one or more heat-correlated parameters of the subsystem 108, examples of which are further described below.

To enable the thermal control system 112 to dynamically control an operation point of the subsystem 108 and manage the generation of heat 304, the monitoring circuit 308 generates at least one feedback metric 314 based on an operation of the subsystem 108 at the current operation point 312. The subsystem 108 passes the feedback metric 314 to the thermal control system 112. The feedback metric 314 at least includes a measured temperature 316 associated with the subsystem 108. The measured temperature 316 can represent an instantaneous temperature that is measured by the sensor 310. In the case of multiple sensors 310, the measured temperature 316 can represent an average or maximum of the instantaneous temperatures measured by the multiple sensors 310.

In some cases, the measured temperature 316 represents a limitation metric 318, which is used to evaluate a current operation of the subsystem 108 with respect to the limitation 302. The limitation metric 318 can provide an indication to the thermal control system 112 of how close an operation of the subsystem 108 is approaching the limitation 302. With this information, the thermal control system 112 can take appropriate action to prevent the subsystem 108 from reaching or exceeding the limitation 302.

In some implementations, the thermal monitoring circuit 308 also monitors and reports a measured power metric 320 of the subsystem 108. The measured power metric 320 can represent an instantaneous amount of power that is consumed by the subsystem 108 or an average amount of power that is consumed by the subsystem 108 over a given time interval. In some cases, the measured power metric 320 represents a trigger metric 322, which is used to enable or disable an aspect of the thermal control system 112, as further described with respect to FIG. 6.

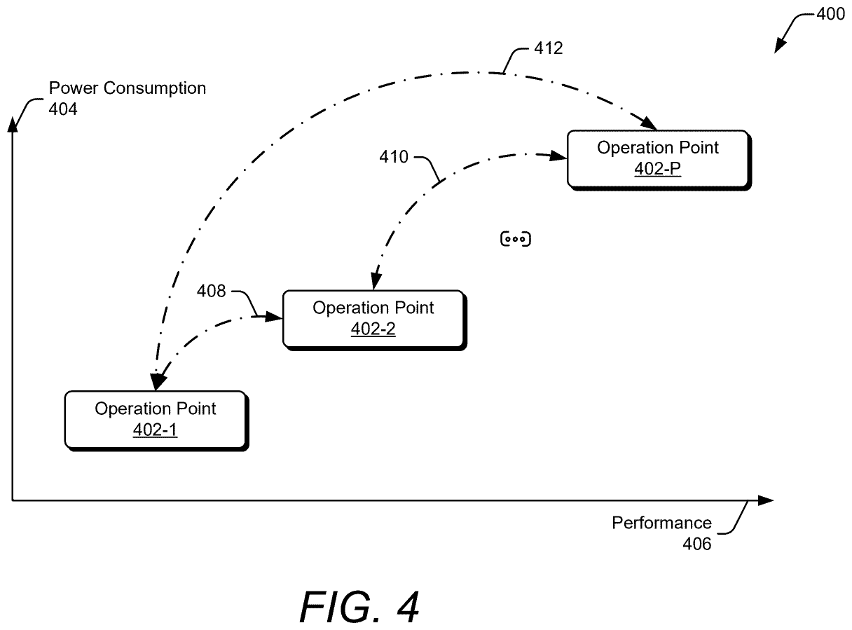

The thermal control system 112 generates a new operation point 324 based on the feedback metric 314. The new operation point 324 specifies at least one heat-correlated parameter 326 (e.g., a heat-correlated operation parameter 326) of the subsystem 108. Example heat-correlated parameters 324 include a clock frequency 328 and a supply voltage 330. If the subsystem 108 represents or includes the display 210, the heat-correlated parameter 326 can include a brightness 332 of the display 210. In the case that the subsystem 108 includes a speaker, a heat-correlated parameter 326 can include a volume 334. Other heat-correlated parameters 324 can include a transmit power associated with a transmitter. In many cases, a heat-correlated parameter 326 has a direct relationship with the heat 304 that is generated by an operation of the subsystem 108. For example, increasing any one of the clock frequency 328, the supply voltage 330, the brightness 332, or the volume 334 can increase an amount of heat 304 that is generated by the subsystem 108. By controlling the operation point of the subsystem 108, the thermal control system 112 can provide dynamic thermal control 114 for the system-on-chip 106. Different operation points can be associated with different levels of power consumption and different levels of performance, as further described with respect to FIG. 4.

FIG. 4 illustrates example operation points 402 of the subsystem 108. In this example, the subsystem 108 can operate at any one of the operation points 402-1, 402-2 . . . 402-P, where P represents a positive integer. A graph 400 depicts an example relationship between the operation points 402 in terms of power consumption 404 and performance 406. Higher levels of performance 406 can enhance the user experience while lower levels of performance 406 can degrade the user experience.

In general, there is a direct relationship between power consumption 404 and performance 406. Operation points 402 associated with higher levels of power consumption 404 are also associated with higher levels of performance 406. Operation points 402 associated with lower levels of power consumption 404 are also associated with lower levels of performance 406. There is also a direct relationship between power consumption 404 and heat generation. Operation points 402 associated with higher levels of power consumption 404 are also associated with higher levels of heat generation. In contrast, operation points 402 associated with lower levels of power consumption 404 are associated with lower levels of heat generation.

The first operation point 402-1 consumes a first amount of power and provides a first level of performance 406. The operation point 402-2 consumes a second amount of power and provides a second level of performance 406. The second amount of power is greater than the first amount of power. Also, the second level of performance 406 is higher than the first level of performance 406. The operation point 402-P consumes a third amount of power and provides a third level of performance 406. The third amount of power is greater than the second amount of power. Also, the third level of performance 406 is higher than the second level of performance 406.

By dynamically changing the operation point 402 of the subsystem 108, the thermal control system 112 can adapt to various workloads and usage of the subsystem 108 while ensuring safety and/or reliability of the system-on-chip 106. In various situations, the thermal control system 112 can adjust the operation point 402 of the subsystem 108 in a slow, gradual manner or a fast, sudden manner. Consider a case in which the subsystem 108 can selectively operate at one of the three operation points 402-1, 402-2, and 402-P. In a first example situation, the thermal control system 112 gradually changes the operation point 402 of the subsystem 108, such as by causing the subsystem 108 to transition between the operation points 402-1 and 402-2 as indicated at 408, or by causing the subsystem 108 to transition between the operation points 402-2 and 402-P as indicated at 410. In these examples, the change in the operation point 402 causes a relatively small change in the power consumption 404 and the performance 406 of the subsystem 108. This gradual change in the operation point 402 can allow for a better user experience as the user 104 may not notice the incremental change in performance 406.

In a second example situation, the thermal control system 112 significantly changes the operation point 402 of the subsystem 108, such as by causing the subsystem 108 to transition between the operation points 402-1 and 402-P. In this example, the change in the operation point 402 causes a relatively large change in the power consumption 404 and the performance 406 of the subsystem 108. This type of situation can occur if an operation of the subsystem 108 is approaching the limitation 302 and the thermal control system 112 has to severely throttle an operation of the subsystem 108. As another example, this situation can occur if a predicted change in the usage of the subsystem 108 indicates that the thermal control system 112 can lift previous-enacted throttling restrictions to enhance the user experience. Example components of the thermal control system 112 are further described with respect to FIG. 5.

FIG. 5 illustrates an example implementation of the thermal control system 112. In the depicted configuration, the thermal control system 112 includes at least one predictor 502, at least one temperature supervisor circuit 504, and at least one resolver 506. The predictor 502 and the temperature supervisor circuit 504 independently generate a thermal control policy recommendation, which includes a recommended temperature threshold, as further described in FIG. 6. The predictor 502 and the temperature supervisor circuit 504 consider different perspectives regarding usage of the subsystem 108 to generate the recommendations. The predictor 502, for instance, considers future use of the subsystem 108 while the temperature supervisor circuit 504 considers current use of the subsystem 108 with respect to a limitation 302 of the subsystem 108.

In more detail, the predictor 502 provides a thermal control policy based on a predicted workload (or usage) of the subsystem 108 (or more generally of the system-on-chip 106). The predicted workload is based on one or more of the feedback metrics 314, as further described with respect to FIG. 6. In some cases, the predictor 502 is implemented using a machine-learned model 508 and is capable of tracking utilization of the subsystem 108 on a user-by-user basis. The machine-learned model 508 can be trained, using supervised learning and/or unsupervised learning, to form a prediction based on this tracking and based on which user 104 is currently using the computing device 102. Based on this prediction, the predictor 502 provides a recommended thermal control policy to the resolver 506.

The temperature supervisor circuit 504 provides a thermal control policy based on a current operation of the subsystem 108. The temperature supervisor circuit 504 can evaluate a limitation metric 318 to determine how close the subsystem 108 is to meeting or exceeding a limitation 302. For example, the temperature supervisor circuit 504 can include at least one comparator 510, which compares the limitation metric 318 to a threshold associated with the limitation 302. Using the results of the limitation comparison, the temperature supervisor circuit 504 provides a recommended thermal control policy to the resolver 506.

The resolver 506 resolves the thermal control policy recommendations provided by the predictor 502 and the temperature supervisor circuit 504 to determine a thermal control policy that is to be used to set the operation point 402 of the subsystem 108. Using the resolver 506, the thermal control system 112 can set the thermal control policy based on a predicted operation of the subsystem 108, as provided by the predictor 502, or based on a current operation of the subsystem 108, as provided by the temperature supervisor circuit 504.

In some cases, the resolver 506 can be designed with a conservative profile that selects one of the recommended thermal control policies that is considered to be the most restrictive (e.g., is associated with a lowest temperature threshold). In other cases, the resolver 506 can have a performance-focused profile that selects one of the recommended thermal control policies that optimizes performance 406 while ensuring operation of the subsystem 108 stays within specified limitations 302. In various implementations, the resolver 506 can be implemented using at least one comparator 512 or at least one machine-learned model 514.

The thermal control system 112 also includes at least one feedback circuit 516 and at least one evaluation circuit 518. The feedback circuit 516 controls a timing associated with the dynamic thermal control 114. This timing can be dynamically changed to adjust a responsiveness of the thermal control system 112, as further described with respect to FIG. 6. In an example implementation, the feedback circuit 516 modifies a feedback metric 314 and passes the modified feedback metric 314 to the evaluation circuit 518.

The evaluation circuit 518 determines a degree to which the current operation of the subsystem 108 is meeting the thermal control policy selected by the resolver 506. In an example implementation, the evaluation circuit 518 includes a subtraction circuit 522, which determines a difference between the selected thermal control policy and the modified feedback metric 314 provided by the evaluation circuit 518.

The thermal control system 112 additionally includes at least one controller 524. The controller 524 determines the new operation point 324 of the subsystem 108 based on information provided by the evaluation circuit 518. The controller 524 can include an operation point mapping circuit 526, which maps the information provided by the evaluation circuit 518 to one of the available operation points 402-1 to 402-P. In an example implementation, the operation point mapping circuit 526 is implemented using a look-up table (LUT). For situations in which the thermal control system 112 provides dynamic thermal control 114 for multiple subsystems 108, the operation point mapping circuit 526 can include a mapping table with throttling limits for the different subsystems 108. This mapping table can also include priorities and specify an order in which different subsystems 108 are to be throttled.

The predictor 502, the temperature supervisor circuit 504, the resolver 506, the feedback circuit 516, the evaluation circuit 518, and the controller 524 can be implemented using any combination of software, hardware, firmware, or fixed logic circuitry. The operation of these components are further described with respect to FIG. 6.

FIG. 6 illustrates an example operation of the thermal control system 112. In the depicted configuration, the predictor 502 and the temperature supervisor circuit 504 are coupled to inputs of the resolver 506. The predictor 502 is also coupled to the controller 524. The evaluation circuit 518 is coupled between the resolver 506 and the controller 524. The feedback circuit 516 is coupled to an input of the evaluation circuit 518.

During operation, the predictor 502 receives one or more feedback metrics 314 from the subsystem 108. In this example, the predictor 502 receives the measured temperature 316 and the measured power metric 320. Other implementations are also possible in which the predictor 502 receives only the measured temperature 316 or only the measured power metric 320. The predictor 502 also receives the operation point 402, which represents a current operation point 312 of the subsystem 108. Using this information, the predictor 502 predicts a workload (or usage) of the subsystem 108, or more generally the system-on-chip 106. Although not explicitly shown in FIG. 6, the predictor 502 can accept additional information from the computing device 102 regarding a current user 104 of the computing device 102 and/or information regarding which applications 206 are currently running on the computing device 102. In this case, the predictor 502 can further predict the workload of the subsystem 108 based on the current user 104 and/or based on the active applications 206.

The temperature supervisor circuit 504 receives the limitation metric 318 from the subsystem 108. As an example, the limitation metric 318 can include the measured temperature 316. The temperature supervisor circuit 504 compares the limitation metric 318 to a limitation threshold 602 associated with the limitation 302. In some implementations, the temperature supervisor circuit 504 further processes the limitation metric 318 prior to performing the comparison. For example, the temperature supervisor circuit 504 can calculate an average of the measured temperature 316 and compare the average to the limitation threshold 602.

The temperature supervisor circuit 504 can optionally receive a trigger metric 322 from the subsystem 108. As an example, the trigger metric 322 can include the measured power metric 320. The trigger metric 322 is used to selectively enable or disable the temperature supervisor circuit 504. For example, the temperature supervisor circuit 504 can perform the comparison if the trigger metric 322 meets a certain condition. For example, the temperature supervisor circuit 504 can perform the comparison if the measured power metric 320 is above a predetermined threshold. Otherwise, the temperature supervisor circuit 504 does not perform the comparison.

The predictor 502 generates a first thermal control policy 604-1 based on the feedback metric(s) 314 and the temperature supervisor circuit 504 generates a second thermal control policy 604-2 based on the comparison. The first thermal control policy 604-1 specifies a first temperature threshold 606-1 (temp threshold 606-1). The second thermal control policy 604-2 specifies a second temperature threshold 606-2 (temp threshold 606-2). The temperature thresholds 606-1 and 606-2 indicate a level for which it is desirable to keep a measured temperature 316 of the subsystem 108 below. Although described with respect to the measured temperature 316, this can additionally or alternatively apply to some calculated variation of the measured temperature 316, such as an average measured temperature. The thermal control policies 604 can include other information in addition to the temperature thresholds 606, such as a time period for enforcing the thermal control policy 604.

The resolver 506 selects one of the thermal control policies 604-1 or 604-2 as a resolved thermal control policy 608. The resolved thermal control policy 608 includes a resolved temperature threshold 610, which represents one of the temperature thresholds 606-1 or 606-2 corresponding to the selected thermal control policy 604.

The predictor 502 can also generate a parameter 612 and pass the parameter 612 to the controller 524. The parameter 612 can provide information regarding the predicted usage of the subsystem 108. In some cases, the parameter 612 can indicate whether the predicted usage is expected to change quickly or slowly. An example parameter 612 can include a gain 614, which adjusts a responsiveness of the controller 524. A large gain 614 can cause the controller 524 to significantly change the operation point 402 of the subsystem 108, an example of which is indicated at 412 in FIG. 4. In contrast, a small gain 614 can cause the controller 524 to minimally change the operation point 402 of the subsystem 108, examples of which are indicated at 408 and 410 in FIG. 4.

Other implementations are also possible in which the temperature supervisor circuit 504 generates a parameter that is similar to the parameter 612. In this case, the resolver 506 can resolve the parameters generated by the predictor 502 and the temperature supervisor circuit 504. The resolver 506 can pass the resolved parameter to the controller 524.

The feedback circuit 516 accepts the measured temperature 316 from the subsystem 108. The feedback circuit 516 generates a modified temperature 616 based on the measured temperature 316. In particular, the feedback circuit 516 can apply a time scale 618 to generate an average or filtered version of the measured temperature 316, which is represented by the modified temperature 616. The time scale 618 can represent a window of time over which the average or filtered version of the measured temperature 316 is calculated. In some situations, the time scale 618 can be set to a value that causes the feedback circuit 516 to pass the measured temperature 316 as the modified temperature 616. In this case, the feedback circuit 516 does not average or filter the measured temperature 316 to generate the modified temperature 616.

Over time, the thermal control system 112 can adjust the time scale 618 applied by the feedback circuit 516 to perform another aspect of dynamic thermal control 114. This effectively changes the feedback signal dynamics of the feedback circuit 516 and impacts a timing of an operation of the evaluation circuit 518 for passing data to the controller 524. By changing the time scale 618, the thermal control system 112 adjusts its responsiveness. In some implementations, the controller 524 can adjust the time scale 618 of the feedback circuit 516 based on the parameter 612. In other implementations, the resolver 506 can adjust the time scale 618 based on the resolved thermal control policy 608.

In general, decreasing the time scale 618 increases a responsiveness of the thermal control system 112 while increasing the time scale 618 decreases a responsiveness of the thermal control system 112. A high-level of responsiveness can enable the thermal control system 112 to make incremental changes to the operation of the subsystem 108. A low-level of responsiveness enables the thermal control system 112 to limit changes so that the user 104 experiences a similar level of performance 406 for longer durations.

Consider the following example in which the responsiveness of the thermal control system 112 changes over time. At a first time interval, a current operation of the subsystem 108 is not near the limitation 302 and/or the predicted usage of the subsystem 108 is determined to remain relatively unchanged. In this case, the thermal control system 112 can take a more “hands-off” approach by setting its responsiveness to a lower level (e.g., by increasing the time scale 618). At a second time interval, the current operation of the subsystem 108 begins to approach the limitation 302 and/or the predicted usage of the subsystem 108 indicates a high likelihood of change. In this case, the thermal control system 112 can take a more active approach by setting its responsiveness to a higher level (e.g., by decreasing the time scale 618).

The evaluation circuit 518 compares the modified temperature 616 to the resolved thermal control policy 608. In more detail, the evaluation circuit 518 generates a temperature offset 624, which represents a difference between the resolved temperature threshold 610 and the modified temperature 616. The temperature offset 624 indicates, to the controller, how much the current temperature of the subsystem 108 differs from the resolved thermal control policy 608. In a sense, it indicates the amount of available margin for operating the subsystem 108.

The controller 524 generates the operation point 402 based on the temperature offset 624 and the parameter 612. The operation point 402 represents the new operation point 324. The controller 524 can cause the new operation point 324 to differ significantly from the current operation point 312 if the gain 614 is relatively high and/or the temperature offset 624 is relatively large. Alternatively, if the gain 614 is relatively small and/or the temperature offset 624 is relatively small, the controller 524 can cause the new operation point 324 to be similar to, or even the same as, the current operation point 312. By dynamically setting the operation point 402 based on the predicted or current operation of the subsystem 108, the thermal control system 112 can enforce appropriate throttling limits while the subsystem 108 operates under different workloads.

### Example Methods

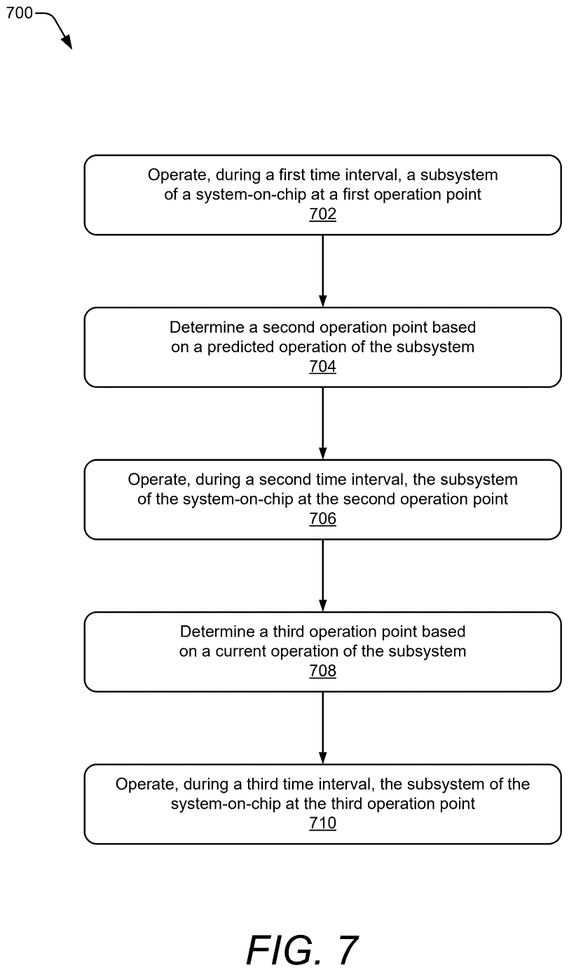

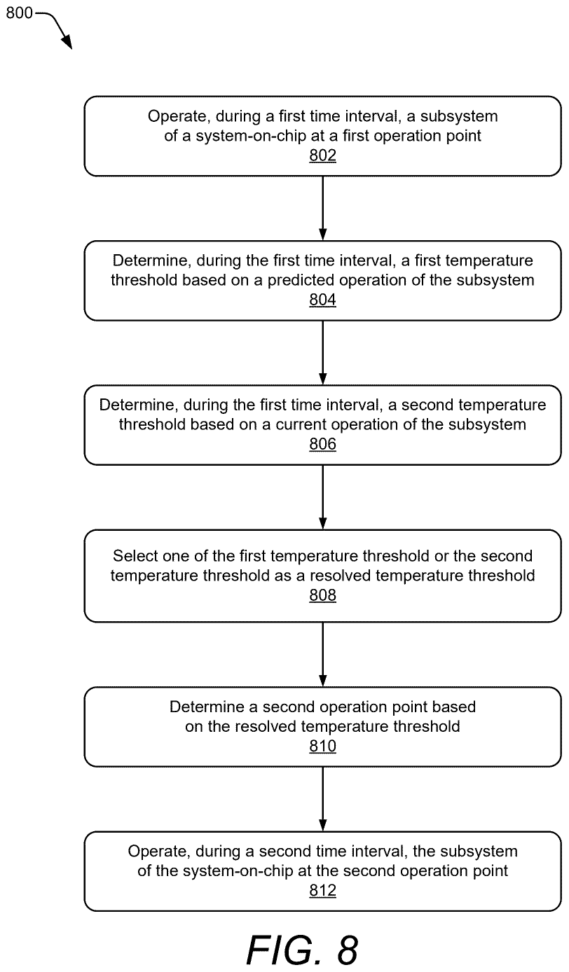

FIGS. 7 and 8 depict example methods 700 and 800 for implementing aspects of dynamic thermal control of a system-on-chip. Methods 700 and 800 are shown as a set of operations (or acts) performed but not necessarily limited to the order or combinations in which the operations are shown herein. Further, any of one or more of the operations may be repeated, combined, reorganized, or linked to provide a wide array of additional and/or alternate methods. In portions of the following discussion, reference may be made to the environment 100 of FIG. 1, and entities detailed in FIGS. 1, 2, and 5, reference to which is made for example only. The techniques are not limited to performance by one entity or multiple entities operating on one device.

At 702 in FIG. 7, a subsystem of a system-on-chip operates at a first operation point during a first time interval. For example, the subsystem 108 operates at operation point 402 during a first time interval. The subsystem 108 represents a heat source 110 and generates heat 304 while operating at the first operation point 402.

At 704, a second operation point is determined based on a predicted operation of the subsystem. For example, the thermal control system 112 determines a second operation point 402 based on a predicted operation of the subsystem 108. In more detail, the resolver 506 selects the thermal control policy 604-1 generated by the predictor 502 and the controller 524 generates the second operation point 402 based on the thermal control policy 604-1, as shown in FIG. 6. The predictor 502 determines the thermal control policy 604-1 based on a predicted usage of the subsystem 108.

The second operation point 402 differs from the first operation point 402 by at least one heat-correlated parameter 326. For example, the second operation point 402 can specify a different clock frequency 328, a different supply voltage 330, a different brightness 332, or a different volume 334 than the first operation point 402.

At 706, the subsystem of the system-on-chip operates at the second operation point during a second time interval. For example, the subsystem 108 operates at the second operation point 402 during the second time interval. The subsystem 108 generates heat 304 while operating at the second operation point 402. The amount of heat 304 generated during the second time interval can differ from the amount of heat 304 generated during the first time interval due to the difference in the first and second operation points 402.

At 708, a third operation point is determined based on a current operation of the subsystem. For example, the thermal control system 112 determines a third operation point 402 based on a current operation of the subsystem 108. In more detail, the resolver 506 selects the thermal control policy 604-2 generated by the temperature supervisor circuit 504 and the controller 524 generates the third operation point 402 based on the thermal control policy 604-2, as shown in FIG. 6. The temperature supervisor circuit 504 determines the thermal control policy 604-2 based on the measured temperature 316 and/or based on a comparison of the limitation metric 318 to the limitation threshold 602.

The third operation point 402 differs from the second operation point 402 by at least one heat-correlated parameter 326. For example, the third operation point 402 can specify a different clock frequency 328, a different supply voltage 330, a different brightness 332, or a different volume 334 than the second operation point 402.

At 710, the subsystem of the system-on-chip operates at the third operation point during a third time interval. For example, the subsystem 108 operates at the third operation point 402 during the third time interval. The subsystem 108 generates heat 304 while operating at the third operation point 402. The amount of heat 304 generated during the third time interval can differ from the amount of heat 304 generated during the second time interval due to the difference in the second and third operation points 402.

At 802 in FIG. 8, a subsystem of a system-on-chip operates at a first operation point during first time interval. For example, the subsystem 108 represents a heat source 110 and generates heat 304 while operating at the first operation point 402. The subsystem 108 represents a heat source 110 and generates heat 304 while operating at the first operation point 402.

At 804, a first temperature threshold is determined during the first time interval based on a predicted operation of the subsystem. For example, the predictor 502 of the thermal control system 112 determines, during the first time interval, the first temperature threshold 606-1, as shown in FIG. 6. More specifically, the predictor 502 determines the first temperature threshold 606-1 based on one or more feedback metrics 314, such as the measured temperature 316 and/or the measured power metric 320 and based on previous usage of the subsystem 108. In some cases, the predictor 502 also determines the first temperature threshold 606-1 based on the current user 104 and the previous usage of the subsystem 108 that is associated with the current user 104.

At 806, a second temperature threshold is determined during the first time interval based on a current operation of the subsystem. For example, the temperature supervisor circuit 504 determines the second temperature threshold 606-2 based on the current operation of the subsystem 108. More specifically, the temperature supervisor circuit 504 determines the second temperature threshold 606-2 based on the measured temperature 316 and/or based on a comparison of the limitation metric 318 to the limitation threshold 602.

At 808, one of the first temperature threshold or the second temperature threshold is selected as a resolved temperature threshold. For example, the resolver 506 selects one of the first temperature threshold 606-1 or the second temperature threshold 606-2 as the resolved temperature threshold 610, as shown in FIG. 6. The resolver 506 can use a comparator 512 and/or a machine-learned model 514 to make the selection.

At 810, a second operation point is determined based on the resolved temperature threshold. For example, the controller 524 determines the operation point 402 (e.g., the new operation point 324) based on the resolved temperature threshold 610. In more detail, the controller 524 determines the operation point 402 based on a temperature offset 624, which represents a difference between the resolved temperature threshold 610 and the modified temperature 616 provided by the feedback circuit 516. The controller 524 can also determine the operation point 402 based on the parameter 612 (e.g., gain 614) provided by the resolver 506. The temperature offset 624 and/or the parameter 612 can determine how drastically the controller 524 changes the operation point 402.

In general, the second operation point 402 differs from the first operation point 402 by at least one heat-correlated parameter 326. For example, the second operation point 402 can specify a different clock frequency 328, a different supply voltage 330, a different brightness 332, or a different volume 334 than the first operation point 402.

At 812, the subsystem of the system-on-chip operates at the second operation point during a second time interval. For example, the subsystem 108 operates at the second operation point 402 during the second time interval. The subsystem 108 generates heat 304 while operating at the second operation point 402. The amount of heat 304 generated during the second time interval can differ from the amount of heat 304 generated during the first time interval due to the difference in the first and second operation points 402.

### Example Computing System

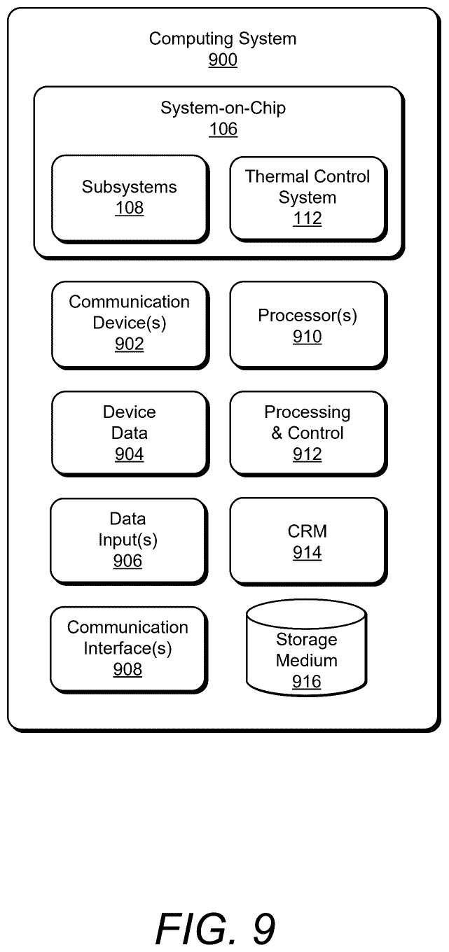

FIG. 9 illustrates various components of an example computing system 900 that can be implemented as any type of client, server, and/or computing device as described with reference to the previous FIGS. 2 and 3 to implement aspects of dynamic thermal control for a subsystem.

The computing system 900 includes communication devices 902 that enable wired and/or wireless communication of device data 904 (e.g., received data, data that is being received, data scheduled for broadcast, or data packets of the data). The device data 904 or other device content can include configuration settings of the device, media content stored on the device, and/or information associated with a user of the device. Media content stored on the computing system 900 can include any type of audio, video, and/or image data. The computing system 900 includes one or more data inputs 906 via which any type of data, media content, and/or inputs can be received.

The computing system 900 also includes communication interfaces 908, which can be implemented as any one or more of a serial and/or parallel interface, a wireless interface, any type of network interface, a modem, and as any other type of communication interface. The communication interfaces 908 provide a connection and/or communication links between the computing system 900 and a communication network by which other electronic, computing, and communication devices communicate data with the computing system 900.

The computing system 900 includes one or more processors 910 (e.g., any of microprocessors, controllers, and the like), which process various computer-executable instructions to control the operation of the computing system 900. Alternatively or in addition, the computing system 900 can be implemented with any one or combination of hardware, firmware, or fixed logic circuitry that is implemented in connection with processing and control circuits which are generally identified at 912. Although not shown, the computing system 900 can include a system bus or data transfer system that couples the various components within the device. A system bus can include any one or combination of different bus structures, such as a memory bus or memory controller, a peripheral bus, a universal serial bus, and/or a processor or local bus that utilizes any of a variety of bus architectures.

The computing system 900 also includes a computer-readable medium 914 (CRM 914), such as one or more memory devices that enable persistent and/or non-transitory data storage (i.e., in contrast to mere signal transmission), examples of which include random access memory (RAM), non-volatile memory (e.g., any one or more of a read-only memory (ROM), flash memory, EPROM, EEPROM, etc.), and a disk storage device. The disk storage device may be implemented as any type of magnetic or optical storage device, such as a hard disk drive, a recordable and/or rewriteable compact disc (CD), any type of a digital versatile disc (DVD), and the like. The computing system 900 can also include a mass storage medium device (storage medium) 916.

The computer-readable medium 914 provides data storage mechanisms to store the device data 904, as well as various device applications and any other types of information and/or data related to operational aspects of the computing system 900. For example, an operating system can be maintained as a computer application with the computer-readable medium 914 and executed on the processors 910. The device applications may include a device manager, such as any form of a control application, software application, signal-processing and control module, code that is native to a particular device, a hardware abstraction layer for a particular device, and so on.

The computing system 900 also includes at least one system-on-chip 106. The system-on-chip 106 includes one or more subsystems 108 and at least one thermal control system 112. In some implementations, the processor 910, the processing and control 912, the computer-readable medium 914, and/or the storage medium 916 can represent one or more subsystems 108 of a system-on-chip 106.

### Conclusion

Although techniques using, and apparatuses including, dynamic control for a system-on-chip have been described in language specific to features and/or methods, it is to be understood that the subject of the appended claims is not necessarily limited to the specific features or methods described. Rather, the specific features and methods are disclosed as example implementations of dynamic control for a system-on-chip.

Some Examples are described below.

Example 1: A method performed by a system-on-chip, the method comprising:

operating, during a first time interval, a subsystem of the system-on-chip at a first operation point;

determining a second operation point based on a predicted operation of the subsystem;

operating, during a second time interval, the subsystem of the system-on-chip at the second operation point;

determining a third operation point based on a current operation of the subsystem; and

operating, during a third time interval, the subsystem of the system-on-chip at the third operation point.

Example 2: The method of example 1, wherein:

the operating of the subsystem at the first operation point causes the subsystem to generate a first amount of heat; and

the operating of the subsystem at the second operation point causes the subsystem to generate a second amount of heat that differs from the first amount of heat.

Example 3: The method of example 1 or 2, wherein the determining of the second operation point comprises:

determining, during the first time interval, a first temperature threshold based on the predicted operation of the subsystem;

determining, during the first time interval, a second temperature threshold based on the current operation of the subsystem; and

generating, during the first time interval, a first resolved temperature threshold by selecting the first temperature threshold instead of the second temperature threshold.

Example 4: The method of example 3, wherein the determining of the second operation point comprises:

determining, during the second time interval, a third temperature threshold based on the predicted operation of the subsystem;

determining, during the second time interval, a fourth temperature threshold based on the current operation of the subsystem; and

generating, during the second time interval, a second resolved temperature threshold by selecting the fourth temperature threshold instead of the third temperature threshold.

Example 5: The method of example 4, wherein:

the determining of the second temperature threshold further comprises determining, during the first time interval, the second temperature threshold based on a comparison of a limitation metric to a limitation threshold associated with the subsystem; and

the determining of the fourth temperature threshold further comprises determining, during the second time interval, the fourth temperature threshold based on a comparison of the limitation metric to the limitation threshold.

Example 6: The method of example 5, wherein:

the limitation metric comprises a measured temperature associated with the subsystem;

the limitation threshold comprises a maximum temperature threshold associated with the subsystem;

the determining of the second temperature threshold further comprises determining, during the first time interval, the second temperature threshold based on the comparison of the measured temperature associated with the subsystem during the first time interval to the maximum temperature threshold; and

the determining of the fourth temperature threshold further comprises determining, during the second time interval, the fourth temperature threshold based on the comparison of the measured temperature associated with the subsystem during the second time interval to the maximum temperature threshold.

Example 7: The method of example 6, wherein the measured temperature comprises an instantaneous temperature measurement associated with the subsystem or an average temperature measurement associated with the subsystem.

Example 8: The method of any one of examples 4 to 7, further comprising:

determining, at the first time interval, a first temperature offset based on a difference between the first resolved temperature threshold and a first modified temperature associated with the subsystem; and

determining, at the second time interval, a second temperature offset based on a difference between the second resolved temperature threshold and a second modified temperature associated with the subsystem, wherein:

the determining of the second operation point comprises determining the second operation point based on the first temperature offset; and

the determining of the third operation point comprises determining the third operation point based on the second temperature offset.

Example 9: The method of example 8, further comprising:

determining the first modified temperature by filtering a measured temperature associated with the subsystem over a first time window; and

determining the second modified temperature by filtering the measured temperature associated with the subsystem over a second time window.

Example 10: The method of example 9, wherein:

the first time window and the second time window are a same time window; or

the first time window and the second time window are different time windows.

Example 11: A method performed by a system-on-chip, the method comprising:

operating, during a first time interval, a subsystem of the system-on-chip at a first operation point;

determining, during the first time interval, a first temperature threshold based on a predicted operation of the subsystem;

determining, during the first time interval, a second temperature threshold based on a current operation of the subsystem;

selecting one of the first temperature threshold or the second temperature threshold as a resolved temperature threshold;

determining a second operation point based on the resolved temperature threshold; and

operating, during a second time interval, the subsystem of the system-on-chip at the second operation point.

Example 12: The method of example 11, wherein:

the determining of the second temperature threshold further comprises determining, during the first time interval, the second temperature threshold based on a comparison of a limitation metric to a limitation threshold associated with the subsystem.

Example 13: The method of example 12, wherein:

the determining of the second temperature threshold is responsive to a trigger metric meeting a condition; and

the trigger metric comprises a measured power metric associated with the subsystem.

Example 14: The method of example 12 or 13, wherein:

the limitation metric comprises a measured temperature associated with the subsystem;

the limitation threshold comprises a maximum temperature threshold associated with the subsystem; and

the determining of the second threshold temperature further comprises determining, during the first time interval, the second threshold temperature based on the comparison of the measured temperature associated with the subsystem during the first time interval to the maximum temperature threshold.

Example 15: The method of any one of examples 11 to 14, further comprising:

determining, during the first time interval, a temperature offset based on a difference between the resolved temperature threshold and a modified temperature associated with the subsystem; and

wherein the determining of the second operation point comprises determining the second operation point based on the temperature offset.

Example 16: The method of any one of examples 11 to 15, further comprising:

determining, during the second time interval, a third temperature threshold based on the predicted operation of the subsystem;

determining, during the second time interval, a fourth temperature threshold based on the current operation of the subsystem;

selecting one of the third temperature threshold or the fourth temperature threshold as a second resolved temperature threshold;

determining a third operation point of the system-on-chip based on the second resolved temperature threshold; and

operating, during a third time interval, the subsystem of the system-on-chip at the third operation point.

Example 17: A system-on-chip comprising:

at least one subsystem, the at least one subsystem configured to:
operate at a first operation point during a first time interval; and
operate at a second operation point during a second time interval; and

at least one thermal control system coupled to the at least one subsystem, the at least one thermal control system configured to:
determine, during the first time interval, a first temperature threshold based on a predicted operation of the subsystem;
determine, during the first time interval, a second temperature threshold based on a current operation of the subsystem;
select one of the first temperature threshold or the second temperature threshold as a resolved temperature threshold;
determine the second operation point based on the resolved temperature threshold; and
cause the at least one subsystem to operate at the second operation point during the second time interval.

Example 18: The system-on-chip of example 17, wherein:

the second operation point is associated with at least one heat-correlated parameter that differs from the first operation point; and

the at least one heat-correlated parameter comprises at least one of the following:
a clock frequency;
a supply voltage;
a brightness;
a volume; or
a transmit power level.

Example 19: The method of example 17 or 18, wherein the thermal control system is further configured to determine, during the first time interval, the second temperature threshold based on a comparison of a limitation metric to a limitation threshold associated with the subsystem.

Example 20: The system-on-chip of any one of examples 17 to 19, wherein:

the at least one system-on-chip is configured to operate at a third operation point during a third time interval; and

the at least one thermal control system is configured to:
determine, during the second time interval, a third temperature threshold based on the predicted operation of the subsystem;
determine, during the second time interval, a fourth temperature threshold based on the current operation of the subsystem;
select, based on the thermal control policy, one of the third temperature threshold or the fourth temperature threshold as a second resolved temperature threshold;
determine the third operation point of the system-on-chip based on the second resolved temperature threshold; and
cause the at least one subsystem to operate at the third operation point during the third time interval.

What is claimed is:

1. A method performed by a system-on-chip, the method comprising:
operating, during a first time interval, a subsystem of the system-on-chip at a first operation point;
determining a second operation point based on a predicted operation of the subsystem;
operating, during a second time interval, the subsystem of the system-on-chip at the second operation point;
determining a third operation point based on a current operation of the subsystem; and
operating, during a third time interval, the subsystem of the system-on-chip at the third operation point.

2. The method of claim 1, wherein:
the operating of the subsystem at the first operation point causes the subsystem to generate a first amount of heat; and
the operating of the subsystem at the second operation point causes the subsystem to generate a second amount of heat that differs from the first amount of heat.

3. The method of claim 1, wherein the determining of the second operation point comprises:
determining, during the first time interval, a first temperature threshold based on the predicted operation of the subsystem;
determining, during the first time interval, a second temperature threshold based on the current operation of the subsystem; and
generating, during the first time interval, a first resolved temperature threshold by selecting the first temperature threshold instead of the second temperature threshold.

4. The method of claim 3, wherein the determining of the second operation point comprises:
determining, during the second time interval, a third temperature threshold based on the predicted operation of the subsystem;
determining, during the second time interval, a fourth temperature threshold based on the current operation of the subsystem; and
generating, during the second time interval, a second resolved temperature threshold by selecting the fourth temperature threshold instead of the third temperature threshold.

5. The method of claim 4, wherein:
the determining of the second temperature threshold further comprises determining, during the first time interval, the second temperature threshold based on a comparison of a limitation metric to a limitation threshold associated with the subsystem; and
the determining of the fourth temperature threshold further comprises determining, during the second time interval, the fourth temperature threshold based on a comparison of the limitation metric to the limitation threshold.

6. The method of claim 5, wherein:
the limitation metric comprises a measured temperature associated with the subsystem;
the limitation threshold comprises a maximum temperature threshold associated with the subsystem;
the determining of the second temperature threshold further comprises determining, during the first time interval, the second temperature threshold based on the comparison of the measured temperature associated with the subsystem during the first time interval to the maximum temperature threshold; and
the determining of the fourth temperature threshold further comprises determining, during the second time interval, the fourth temperature threshold based on the comparison of the measured temperature associated with the subsystem during the second time interval to the maximum temperature threshold.

7. The method of claim 6, wherein the measured temperature comprises an instantaneous temperature measurement associated with the subsystem or an average temperature measurement associated with the subsystem.

8. The method of claim 4, further comprising:
determining, at the first time interval, a first temperature offset based on a difference between the first resolved temperature threshold and a first modified temperature associated with the subsystem; and
determining, at the second time interval, a second temperature offset based on a difference between the second resolved temperature threshold and a second modified temperature associated with the subsystem, wherein:
the determining of the second operation point comprises determining the second operation point based on the first temperature offset; and
the determining of the third operation point comprises determining the third operation point based on the second temperature offset.

9. The method of claim 8, further comprising:
determining the first modified temperature by filtering a measured temperature associated with the subsystem over a first time window; and
determining the second modified temperature by filtering the measured temperature associated with the subsystem over a second time window.

10. The method of claim 9, wherein:
the first time window and the second time window are a same time window; or
the first time window and the second time window are different time windows.

11. A method performed by a system-on-chip, the method comprising:
operating, during a first time interval, a subsystem of the system-on-chip at a first operation point;
determining, during the first time interval, a first temperature threshold based on a predicted operation of the subsystem;
determining, during the first time interval, a second temperature threshold based on a current operation of the subsystem;
selecting one of the first temperature threshold or the second temperature threshold as a resolved temperature threshold;
determining a second operation point based on the resolved temperature threshold; and
operating, during a second time interval, the subsystem of the system-on-chip at the second operation point.

12. The method of claim 11, wherein:
the determining of the second temperature threshold further comprises determining, during the first time interval, the second temperature threshold based on a comparison of a limitation metric to a limitation threshold associated with the subsystem.

13. The method of claim 12, wherein:
the determining of the second temperature threshold is responsive to a trigger metric meeting a condition; and
the trigger metric comprises a measured power metric associated with the subsystem.

14. The method of claim 12, wherein:
the limitation metric comprises a measured temperature associated with the subsystem;
the limitation threshold comprises a maximum temperature threshold associated with the subsystem; and
the determining of the second threshold temperature further comprises determining, during the first time interval, the second threshold temperature based on the comparison of the measured temperature associated with the subsystem during the first time interval to the maximum temperature threshold.

15. The method of claim 11, further comprising:
determining, during the first time interval, a temperature offset based on a difference between the resolved temperature threshold and a modified temperature associated with the subsystem; and
wherein the determining of the second operation point comprises determining the second operation point based on the temperature offset.

16. The method of claim 11, further comprising:
determining, during the second time interval, a third temperature threshold based on the predicted operation of the subsystem;
determining, during the second time interval, a fourth temperature threshold based on the current operation of the subsystem;
selecting one of the third temperature threshold or the fourth temperature threshold as a second resolved temperature threshold;
determining a third operation point of the system-on-chip based on the second resolved temperature threshold; and
operating, during a third time interval, the subsystem of the system-on-chip at the third operation point.

17. A system-on-chip comprising:
at least one subsystem, the at least one subsystem configured to:
operate at a first operation point during a first time interval; and
operate at a second operation point during a second time interval; and
at least one thermal control system coupled to the at least one subsystem, the at least one thermal control system configured to:
determine, during the first time interval, a first temperature threshold based on a predicted operation of the subsystem;
determine, during the first time interval, a second temperature threshold based on a current operation of the subsystem;
select one of the first temperature threshold or the second temperature threshold as a resolved temperature threshold;
determine the second operation point based on the resolved temperature threshold; and
cause the at least one subsystem to operate at the second operation point during the second time interval.

18. The system-on-chip of claim 17, wherein:
the second operation point is associated with at least one heat-correlated parameter that differs from the first operation point; and
the at least one heat-correlated parameter comprises at least one of the following:
a clock frequency;
a supply voltage;
a brightness;
a volume; or
a transmit power level.

19. The system-on-chip of claim 17, wherein the thermal control system is further configured to determine, during the first time interval, the second temperature threshold based on a comparison of a limitation metric to a limitation threshold associated with the subsystem.

20. The system-on-chip of claim 17, wherein:
the at least one system-on-chip is configured to operate at a third operation point during a third time interval; and
the at least one thermal control system is configured to:
determine, during the second time interval, a third temperature threshold based on the predicted operation of the subsystem;
determine, during the second time interval, a fourth temperature threshold based on the current operation of the subsystem;
select one of the third temperature threshold or the fourth temperature threshold as a second resolved temperature threshold;
determine the third operation point of the system-on-chip based on the second resolved temperature threshold; and
cause the at least one subsystem to operate at the third operation point during the third time interval.
